(19) United States
(12) Patent Application Publication
(10) Pub. No.: US 2021/0193634 A1
(43) Pub. Date: Jun. 24, 2021

(54) EPITAXIAL BASE PLATE, MANUFACTURING METHOD FOR MAKING THE SAME AND APPARATUS

(71) Applicant: Chengdu Vistar Optoelectronics Co., Ltd., Chengdu (CN)

(72) Inventors: Enqing GUO, Chengdu (CN); Rubo XING, Chengdu (CN); Xiuqi HUANG, Chengdu (CN)

(73) Assignee: Chengdu Vistar Optoelectronics Co., Ltd., Chengdu (CN)

(21) Appl. No.: 17/191,997

(22) Filed: Mar. 4, 2021

Related U.S. Application Data
(63) Continuation of application No. PCT/CN2019/075758, filed on Feb. 21, 2019.

(30) Foreign Application Priority Data
Oct. 31, 2018 (CN) 201811290471.5

(51) Int. Cl. H01L 25/075; H01L 27/12; H01L 33/44; H01L 33/52; H01L 33/62; H01L 33/32

(52) U.S. Cl. CPC H01L 25/0753; H01L 27/1214; H01L 33/44; H01L 33/52; H01L 2933/0066; H01L 33/32; H01L 2933/0025; H01L 2933/005; H01L 33/62

(57) ABSTRACT

An epitaxial base plate including a base plate body; a plurality of bosses arranged on the base plate body in an array; a plurality of contact electrodes correspondingly disposed on tops of the bosses; a planarization layer covering the bosses and a region of the base plate body without being covered by the bosses. The planarization layer defines a plurality of first through holes corresponding to the bosses to expose plurality of contact electrodes via the plurality of first through holes; and a plurality of pads arranged on the planarization layer in an array and electrically connected to the corresponding contact electrodes via the first through holes. An area of a vertical projection of the pad on the base plate body is greater than an area of a vertical projection of the contact electrode on the base plate body.

### CROSS-REFERENCE TO RELATED APPLICATIONS

The present disclosure is a continuation-application of International Patent Application No. PCT/CN2019/075758 filed Feb. 21, 2019, which claims foreign priority of Chinese Patent Application No. 201811290471.5, filed on Oct. 31, 2018 in the China National Intellectual Property Administration, the contents of all of which are hereby incorporated by reference.

### TECHNICAL FIELD

The described embodiments relate to the field of display technology, and particularly to an epitaxial base plate, a manufacturing method for making the same and an apparatus.

### BACKGROUND

In recent years, semiconductor illumination technology has become increasingly mature, with costs getting lower and scales of industry becoming saturated, which has provided better technical support for development of the LED display technology.

Micro-LEDs (Micro Light Emitting Diodes) have such advantages as great brightness, a high response speed, low power consumption, long service life, etc., so that Micro-LED display technology becomes a research hotspot of next-generation display technology. However, the Micro-LED display technology is still immature, and many technical problems remain to be solved.

Due to an extremely small size of the Micro-LED, pattern sizes of the electrode layer and passivation layer thereof are smaller, which poses great challenges to accuracy of alignment bonding and process control and is not conducive to a success rate of the alignment bonding.

### SUMMARY OF THE INVENTION

The main problems solved by the present application are to provide an epitaxial base plate and a manufacturing method for making the same and an apparatus.

In order to solve the above technical problems, the technical solution adopted by the present application is to provide an epitaxial base plate, including: a base plate body; a plurality of bosses, arranged on the base plate body in an array; a plurality of contact electrodes, correspondingly disposed on the top of the bosses; a planarization layer, covering the bosses and a region of the base plate body without being covered by the bosses, where the planarization layer defines a plurality of first through holes corresponding to the bosses to expose the plurality of contact electrodes via the plurality of first through holes; a plurality of pads arranged on the planarization layer in an array and electrically connected to corresponding contact electrodes via the first through holes, an area of a vertical projection of the pads on the base plate body is larger than an area of a vertical projection of the contact electrodes on the base plate body.

In order to solve the above technical problems, another technical solution adopted by the present application is to provide a method for manufacturing an epitaxial base plate. The method includes: providing a base plate body; forming, on the base plate body, a plurality of bosses arranged in an array; forming contact electrodes correspondingly on the top of the bosses; covering, with a planarization layer, the bosses and a region of the base plate body without being covered by the bosses, and defining a plurality of first through holes on the planarization layer corresponding to the bosses to expose the plurality of contact electrodes via the plurality of first through holes; and forming, on the planarization layer, a plurality of pads arranged in an array, where the pads are each electrically connected to corresponding contact electrodes via corresponding first through holes, and an area of a vertical projection of the pads on the base plate body is larger than an area of a vertical projection of the contact electrodes on the base plate body.

In order to solve the above technical problems, the technical solution adopted by the present application is to provide an apparatus, including: a base, wherein a plurality of driving elements are located on the base; a planarization layer located above the driving elements, a plurality of light emitting units embedded in the planarization layer, wherein tops of the light emitting units are planar with a top surface of the planarization layer; a contact electrode being in contact with a bottom of each of the light emitting units; and a plurality of pads located between the base and the planarization layer, each of the pads including a connection portion connecting a corresponding contact electrode and an extending portion extending from the connection portion; wherein the connecting portion is embedded in the planarization layer, and the extending portion is sandwiched between a top surface of a corresponding driving element and a bottom surface of the planarization layer; and common electrode located on the top surface of the planarization layer; wherein an area of vertical projection of each of the pads on the common electrode is larger than an area of vertical projection of the corresponding contact electrode on the common electrode.

### BRIEF DESCRIPTION OF THE DRAWINGS

FIG. 1 is a schematic structural diagram of an epitaxial base plate according to an embodiment of the present disclosure.

FIG. 2 is a schematic structural diagram of an epitaxial base plate after pads and contact electrodes are removed according to an embodiment of the present disclosure.

FIG. 3 is a schematic flowchart of a method for manufacturing an epitaxial base plate according to an embodiment of the present disclosure.

FIG. 4 is a schematic diagram of manufacturing processes S11-S16 of an epitaxial base plate according to an embodiment of the present disclosure.

FIG. 5 is a schematic diagram of manufacturing processes S17-S18 of an epitaxial substrate according to an embodiment of the present disclosure.

FIG. 6 is a schematic structural diagram of an apparatus according to an embodiment of the present disclosure.

### DETAILED DESCRIPTION

The technical solutions in the embodiments of the present application will be clearly and completely described below in conjunction with the drawings in the embodiments of the present application. Obviously, the described embodiments are only a part of the embodiments of the present application, rather than all of the embodiments. Based on the embodiments of the present application, all other embodiments obtained by persons of ordinary skill in the art without expending inventive labor shall fall within the protection scope of the present application.

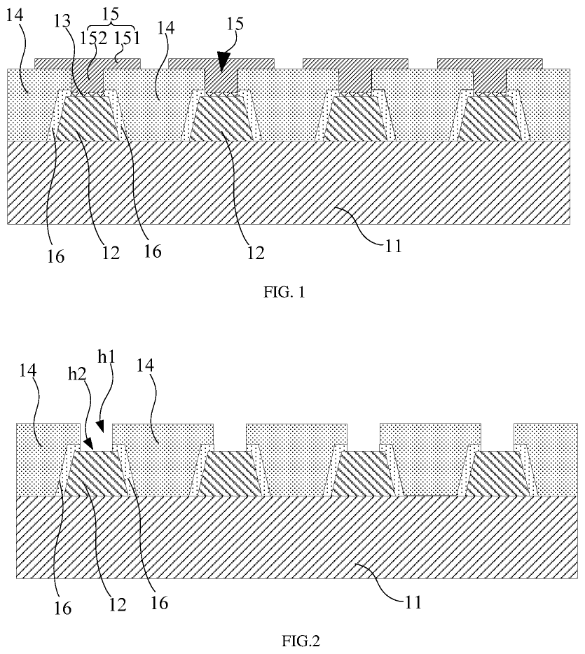

Referring to FIG. 1 and FIG. 2, the epitaxial base plate includes a base plate body 11, a plurality of bosses 12, a plurality of contact electrodes 13, a planarization layer 14, and a plurality of pads 15.

The base plate body 11 may include a substrate and an epitaxial layer formed on the substrate. A material of the substrate may be a sapphire material, silicon, or the like. A material of the epitaxial layer may be gallium nitride (GaN).

The plurality of bosses 12 are arranged on the base plate body 11 in an array. The bosses 12 may be LED light-emitting units.

For example, the bosses 12 may include at least a light-emitting layer, and an N-type semiconductor layer and a P-type semiconductor layer which are located on both sides of the light-emitting layer.

For example, the bosses 12 may be electroluminescent elements, i.e., elements that can emit light, when energized. The bosses 12 may be Micro LEDs. Alternatively, a size of the bosses 12 in a direction perpendicular to a light output direction (for example, a transverse size in the Figure) is between 1 μm and 100 μm, and a size thereof in the light output direction (for example, a longitudinal size in the Figure) is between 0.5 μm and 10 μm.

The bosses 12 may also be OLED (Organic Light-Emitting Diode) light-emitting units. It should be understood that the bosses 12 might be other light-emitting units, without any limitation set in the embodiments of the present application.

The bosses 12 get access to driving current or voltage via the contact electrodes 13.

The contact electrodes 13 correspond one by one to the bosses 12. The contact electrodes 13 are correspondingly disposed on the top of the bosses 12. The contact electrodes 13 are in electrical contact with corresponding bosses 12.

The planarization layer 14 covers the bosses 12 and a region of the base plate body 11 without being covered by the bosses 12.

The planarization layer 14 defines a plurality of first through holes h1 corresponding to the bosses 12, so that the plurality of contact electrodes 13 are exposed via the plurality of first through holes h1.

The plurality of pads 15 are arranged on the planarization layer 14 in an array, and are electrically connected to corresponding contact electrodes 13 via the first through holes h1.

Alternatively, the pads 15 are configured to perform alignment bonding with a driving circuit on a corresponding driving base plate.

An area of a vertical projection of the pads 15 on the base plate body 11 is larger than an area of a vertical projection of the contact electrodes 13 on the base plate body 11.

Alternatively, the vertical projection of the pads 15 on the base plate body 11 completely covers the vertical projection of the contact electrodes 13 on the base plate body 11.

In the above manner, since the vertical projection of the pads 15 on the base plate body 11 completely covers the vertical projection of the contact electrodes 13 on the base plate body 11, to facilitate electrical connection between the contact electrodes 13 and the pads 15, the designed contact structure does not occupy a transverse size of the epitaxial substrate. Since the pads 15 are configured to be connected to the corresponding contact electrodes 13, when the driving base plate is aligned with the epitaxial base plate, it is applicable for alignment with the array of pads 15. The planarization layer 14 is designed such that the area of the pads 15 can be designed to be larger than that of the contact electrodes 13. Since the area of the pads 15 is larger than that of the contact electrodes 13, the difficulty of alignment with the array of pads 15 is reduced, as compared with direct alignment with the contact electrodes 13, thereby making it possible to increase the alignment success rate of the epitaxial base plate and the driving base plate. Further, the design of the planarization layer 14 may prevent the pads 15 from causing a short circuit or static electricity.

Alternatively, the vertical projection of the pads 15 on the base plate body 11 completely covers vertical projection of the bosses 12 on the base plate body 11. The area of the vertical projection of the pads 15 on the base plate body 11 is further larger than an area of the vertical projection 12 of the bosses 12 on the base plate body 11.

In the above manner, the vertical projection of the pads 15 on the base plate body 11 is further configured to completely cover the vertical projection of the bosses 12 on the base plate body 11, and the projection area of the pads 15 is made larger than that of the bosses 12, thereby making it possible to further improve the alignment success rate without occupying an additional transverse size of the base plate body 11. Transverse space between two adjacent bosses 12 is employed to increase a contact area of the pads 15.

Alternatively, the area of the vertical projection of the pads 15 on the base plate body 11 is at least twice the area of the vertical projection of the bosses 12 on the base plate body 11.

In the above manner, by further configuring the area of the pads 15 to be more than twice the area of the bosses 12, the alignment success rate of the epitaxial base plate and the driving base plate is guaranteed.

Alternatively, the area of the pads 15 is between two and four times the area of the bosses 12, so that it is possible to guarantee the displaying effect without affecting the pixel density, in the case of guaranteeing the alignment success rate of the epitaxial base plate and the driving base plate.

Alternatively, the area of the pads 15 is between two and three times the area of the bosses 12. In this case, the displaying effect may be better guaranteed.

Alternatively, the pads 15 are arranged in a T-shape. Specifically, the pads 15 may include an epitaxial portion 151 and a connecting portion 152. The connecting portion 152 is perpendicularly connected to the epitaxial portion 151. For example, the connecting portion 152 is provided perpendicular to a surface of the base plate body 11, and the epitaxial portion 151 is provided parallel to the surface of the base plate body 11.

The epitaxial portion 151 is disposed on the planarization layer 14. The connecting portion 152 is disposed within the first through holes h1. The connecting portion 152 is configured to electrically connect the epitaxial portion 151 and the contact electrodes 13.

Alternatively, vertical projection of the epitaxial portion 151 on the base plate body 11 completely covers vertical projection of the connecting portion 152 and the first through holes h1 on the base plate body 11.

Alternatively, an area of the vertical projection of the epitaxial portion 151 on the base plate body 11 is further larger than an area of the vertical projection of the connecting portion 152 and the first through holes h1 on the base plate body 11.

As shown in FIG. 1, in the present embodiment, the epitaxial portion 151 has an equal cross-sectional area starting from the planarization layer in a direction away from the base plate body 11. In this manner, an area of a contact surface of a side of the pads 15 away from the base plate body 11 may be maximized.

In other embodiments, the cross-sectional area of the epitaxial portion may further gradually decrease starting from the planarization layer in the direction away from the base plate body 11. In this manner, the contact area between the pads 15 and the planarization layer 14 may be increased to make engagement between the pads 15 and the planarization layer 14 more secure.

Alternatively, the epitaxial base plate may further include a passivation layer 16 that is interposed between the bosses 12 and the planarization layer 14. The passivation layer 16 has a plurality of second through holes h2 exposing the contact electrodes 13.

Alternatively, a material of the passivation layer 16 may be silicon nitride (SiNx), silicon oxide (SiOx), or a stacked structure of silicon nitride (SiNx) and silicon oxide (SiOx).

In the above manner, the bosses 12 may be protected by providing the passivation layer 16, to avoid the planarization layer 14 directly disposed on the bosses 12 from eroding the bosses 12.

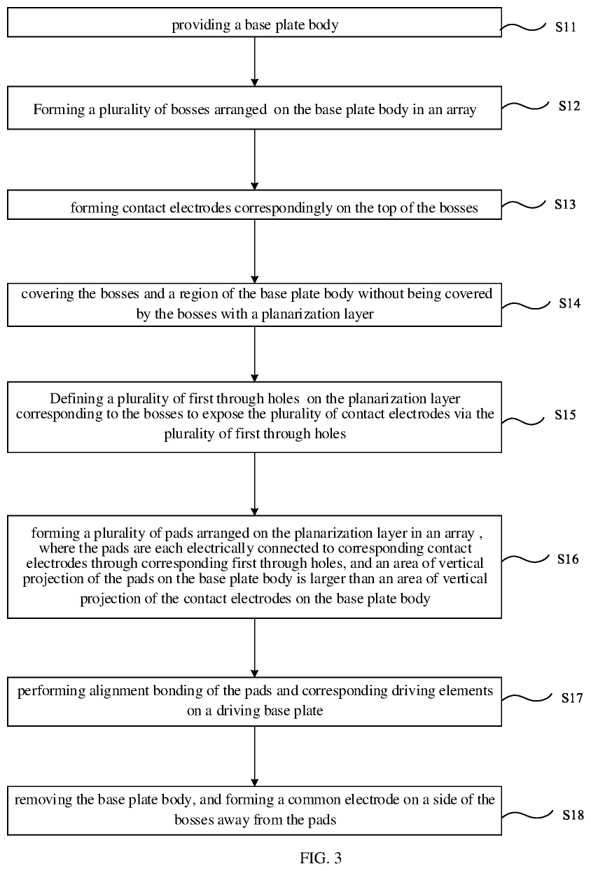

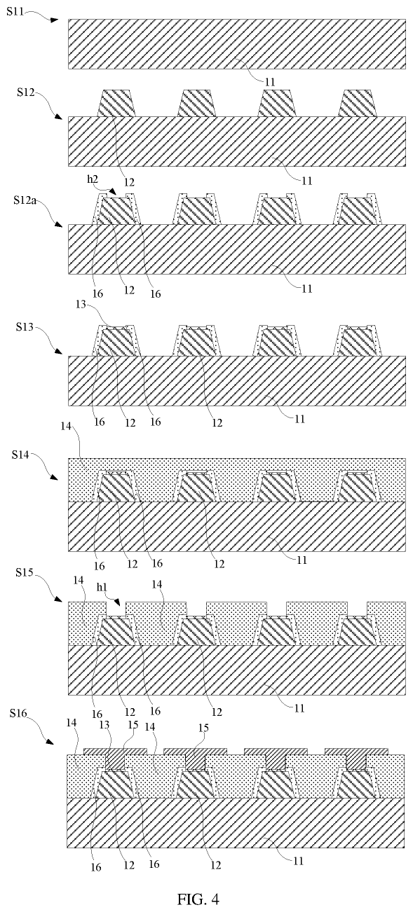

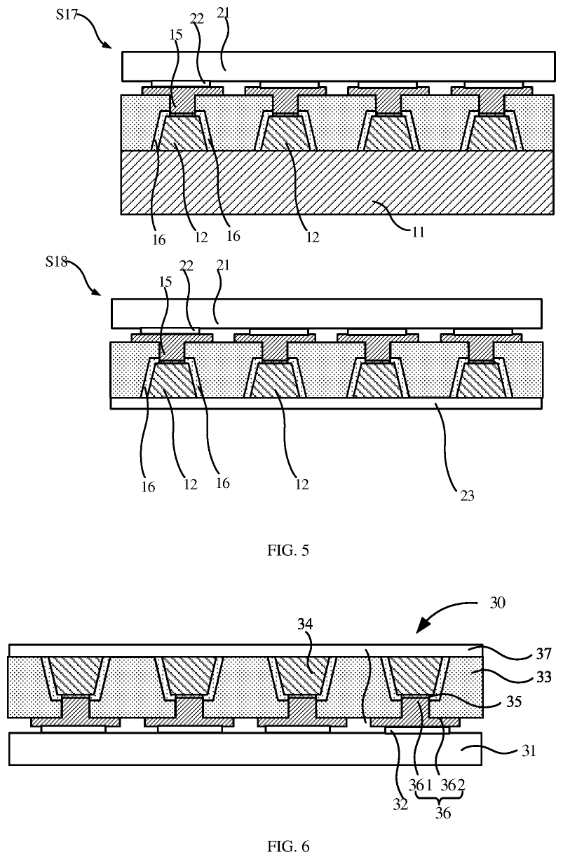

Referring to FIG. 3, FIG. 4, and FIG. 5, the method for manufacturing an epitaxial base plate may include steps as follows.

At block S11, the method may include providing a base plate body.

The base plate body 11 may include a substrate and an epitaxial layer formed on the substrate. A material of the substrate may be a sapphire material, silicon, or the like. A material of the epitaxial layer may be gallium nitride (GaN).

At block S12, the method may include forming a plurality of bosses arranged on the base plate body in an array.

The bosses 12 are formed on a surface of a side of the epitaxial layer away from the substrate. The bosses 12 may be LED light-emitting units. For example, the bosses 12 may include at least a light-emitting layer, and an N-type semiconductor layer and a P-type semiconductor layer which are located on both sides of the light-emitting layer. For example, the bosses 12 may be Micro LEDs. Alternatively, a size of the bosses 12 in a direction perpendicular to a light output direction (for example, a transverse size in the Figure) is between 1 μm and 100 μm, and a size thereof in the light output direction (for example, a longitudinal size in the Figure) is between 0.5 μm and 10 μm.

The bosses 12 may also be OLED (Organic Light-Emitting Diode) light-emitting units. It should be understood that the bosses 12 may be other electroluminescent elements, without any limitation set in the embodiments of the present application.

Specific methods of forming a plurality of bosses 12 on the base plate body 11 arranged in an array may include: forming a whole layer of a boss material layer on the base plate body 11; and performing an etching treatment on the whole layer of the boss material layer to form a plurality of bosses 12 arranged in an array.

Alternatively, the forming the whole layer of the boss material layer on the base plate body 11 may include: growing various layers of the LEDs on the epitaxial layer by means of epitaxy.

Alternatively, the performing the etching treatment on the whole layer of the boss material layer to form a plurality of bosses 12 arranged in the array may specifically include: adopting such semiconductor processes as photolithography and ICP (inductively coupled plasma) etching.

Alternatively, subsequent to the block S12, block S12a may be included: forming a passivation layer 16 on side walls of the bosses 12 and a region of a part of top walls of the bosses 12; and defining, on the passivation layer 16, a plurality of second through holes h2 exposing the contact electrodes. The manner of defining the passivation layer 16 may be vapor deposition, e.g., physical vapor deposition or chemical vapor deposition, and specifically may be PECVD (Plasma Enhanced Chemical Vapor Deposition, plasma enhanced chemical vapor deposition).

At block S13, the method may include forming contact electrodes correspondingly on the top of the bosses.

The bosses 12 get access to driving current or voltage via the contact electrodes 13. The contact electrodes 13 are formed on the bosses via a metal lift off process or an EB/Sputter (electron beam/sputter), photolithography, and etching process.

Alternatively, the contact electrodes 13 are formed in the second through holes h2.

At block S14, the method may include covering the bosses and a region of the base plate body without being covered by the bosses with a planarization layer.

For example, a planarization layer 14 is formed on the bosses 12 and a region of the base plate body 11 without being covered by the bosses 12 via a deposition process. The specific deposition manner may be physical vapor deposition or chemical vapor deposition.

At block S15, the method may include defining a plurality of first through holes on the planarization layer corresponding to the bosses to expose the plurality of contact electrodes via the plurality of first through holes.

The first through holes h1 corresponding to the bosses 12 are defined on the planarization layer 14, so that the contact electrodes 13 are exposed via the first through holes h1. The formation of the planarization layer 14 and the first through holes h1 may be achieved with a polymer planarization material of photosensitive properties via a photolithography process.

At block S16, the method may include forming a plurality of pads arranged on the planarization layer in an array, where the pads are each electrically connected to corresponding contact electrodes through corresponding first through holes, and an area of vertical projection of the pads on the base plate body is larger than an area of vertical projection of the contact electrodes on the base plate body.

A plurality of pads 15 arranged in an array are formed on the planarization layer 14. For the area size relationship between the pads 15 and the contact electrodes 13 and the bosses 12, see the description of the foregoing embodiments, and details are not described herein again.

At block S17, the method may include performing alignment bonding of the pads and corresponding driving elements on a driving base plate.

For example, the plurality of pads 15 arranged in an array and a plurality of driving elements 22 on a driving base plate 21 are subjected to alignment bonding, so that the plurality of pads 15 arranged in the array and the plurality of driving elements 22 on the driving base plate 21 are electrically connected in a manner of corresponding one by one to each other.

At block S18, the method may include removing the base plate body, and forming a common electrode on a side of the bosses away from the pads.

The base plate body 11 is removed, and a whole layer of common electrode 23 is formed on a side of the bosses 12 away from the pads 15. All of the bosses 12 share a common electrode 23, and the other electrodes of the bosses 12 are connected to different driving elements 22.

In one embodiment, referring to FIG. 6, an apparatus 30 may include a base 31, a plurality of driving elements 32, a planarization layer 33, a plurality of light emitting units 34 embedded in the planarization layer 33, a plurality of contact electrodes 35 being in contact with bottoms of the light emitting units 34, a plurality of pads 36 located between the base and the planarization layer 33 and a common electrode 37 located on a top surface of the planarization layer 33.

A plurality of driving elements 32 are located on the base 31. The planarization layer 33 is located above the driving elements 32.

Tops of the light emitting units 34 are planar with a top surface of the planarization layer 33.

Each of the pads 36 may include a connection portion 361 connecting a corresponding contact electrode 35 and an extending portion 362 extending from the connection portion 361. The connecting portion 361 is embedded in the planarization layer 33, and the extending portion 362 is sandwiched between a top surface of a corresponding driving element 32 and a bottom surface of the planarization layer 33.

An area of vertical projection of each of the pads 36 on the common electrode 37 is larger than an area of vertical projection of the corresponding contact electrode 35 on the common electrode 37.

The epitaxial base plate of the present application includes: a base plate body; a plurality of bosses arranged on the base plate body in an array; a plurality of contact electrodes correspondingly disposed on the top of the bosses; a planarization layer covering the bosses and a region of the base plate body not covered by the bosses, where the planarization layer defines first through holes corresponding to the bosses, so that the contact electrodes are exposed via the first through holes; a plurality of pads arranged on the planarization layer in an array and electrically connected to corresponding contact electrodes via the first through holes, where an area of vertical projection of the pads on the base plate body is larger than an area of vertical projection of the contact electrodes on the base plate body. In the above manner, since the pads are configured to be connected to the corresponding contact electrodes, when the driving base plate is aligned with the epitaxial base plate, it is applicable for alignment with a pad array. The planarization layer is designed such that an area of the pads may be designed to be larger than that of the contact electrodes. Since the area of the pads is larger than that of the contact electrodes, the difficulty of alignment with the pads is reduced, thereby making it possible to increase the alignment success rate of the epitaxial base plate and the driving base plate. The epitaxial base plate structure is such that an allowable error range of alignment bonding to the driving base plate can increase by at least 10%, which varies depending on a duty ratio of the bosses on the epitaxial base plate. When the duty ratio of the bosses on the epitaxial base plate is 10%, the allowable error range can be increased to approximately 10 times, so the increasing effect is significant.

The foregoing are only embodiments of the present application, and thus do not limit the patent scope of the present application. Any equivalent structure or equivalent process transformation made by using the description and drawings of the present application, either directly or indirectly applied in other related technical fields, shall be included in the scope of patent protection of the present application.

What is claimed is:

1. An epitaxial base plate comprising:
a base plate body;
a plurality of bosses, arranged on the base plate body in an array;
a plurality of contact electrodes, correspondingly disposed on tops of the bosses;
a planarization layer, covering the bosses and a region of the base plate body without being covered by the bosses, wherein the planarization layer defines a plurality of first through holes corresponding to the bosses to expose the plurality of contact electrodes via the plurality of first through holes;
a plurality of pads arranged on the planarization layer in an array and electrically connected to the corresponding contact electrodes via the first through holes, an area of a vertical projection of the pads on the base plate body being larger than an area of a vertical projection of the contact electrodes on the base plate body.

2. The epitaxial base plate according to claim 1, wherein the vertical projection of the pads on the base plate body completely covers the vertical projection of the contact electrodes on the base plate body.

3. The epitaxial base plate according to claim 2, wherein the vertical projection of the pads on the base plate body completely covers vertical projection of the bosses on the base plate body, and the area of the vertical projection of the pads on the base plate body is larger than an area of the vertical projection of the bosses on the base plate body.

4. The epitaxial base plate according to claim 3, wherein the area of the vertical projection of the pads on the base plate body is at least twice the area of the vertical projection of the bosses on the base plate body.

5. The epitaxial base plate according to claim 4, wherein an area of the pads is between two and four times an area of the bosses.

6. The epitaxial base plate according to claim 5, wherein the area of the pads is between two and three times the area of the bosses.

7. The epitaxial base plate according to claim 1, wherein the pads are provided in a T-shape, and each of the pads comprises an epitaxial portion provided on the planarization layer, and a connecting portion disposed in a first through hole and configured to be electrically connected with the epitaxial portion and the contact electrodes, a vertical projection of the epitaxial portion on the base plate body completely covering a vertical projection of the connecting portion and the first through holes on the base plate body, and an area of the vertical projection of the epitaxial portion on the base plate body is larger than an area of the vertical projection of the connecting portion and the first through holes on the base plate body.

8. The epitaxial base plate according to claim 7, wherein a cross-sectional area of the epitaxial portion gradually decreases in a direction starting from being close to the base plate body to be away from the base plate body.

9. The epitaxial base plate according to claim 7, wherein the epitaxial portion has an equal cross-sectional area in the direction starting from being close to the base plate body to be away from the base plate body.

10. The epitaxial base plate according to claim 1, further comprises a passivation layer, interposed between the bosses and the planarization layer, and the passivation layer has a plurality of second through holes exposing the contact electrodes.

11. The epitaxial base plate according to claim 10, wherein the passivation layer is silicon nitride, silicon oxide, or a stacked structure of silicon nitride and silicon oxide.

12. The epitaxial base plate according to claim 1, wherein the bosses are LED light-emitting units, and each of the bosses comprises a light-emitting layer, and an N-type semiconductor layer and a P-type semiconductor layer which are located on both sides of the light-emitting layer.

13. The epitaxial base plate according to claim 12, wherein a size of the bosses along a direction perpendicular to a light output direction is between 1 μm and 100 μm, and a size of the bosses along the light output direction is between 0.5 μm and 10 μm.

14. The epitaxial base plate according to claim 1, wherein the base plate body comprises a substrate and an epitaxial layer formed on the substrate.

15. The epitaxial base plate according to claim 14, wherein a material of the substrate is sapphire material or silicon, a material of the epitaxial layer is gallium nitride.

16. An apparatus, comprising: a base, wherein a plurality of driving elements are located on the base;
a planarization layer located above the driving elements, a plurality of light emitting units embedded in the planarization layer, wherein tops of the light emitting units are planar with a top surface of the planarization layer;
a contact electrode being in contact with a bottom of each of the light emitting units; and
a plurality of pads located between the base and the planarization layer, each of the pads comprising a connection portion connecting a corresponding contact electrode and an extending portion extending from the connection portion; wherein the connecting portion is embedded in the planarization layer, and the extending portion is sandwiched between a top surface of a corresponding driving element and a bottom surface of the planarization layer; and
a common electrode located on the top surface of the planarization layer; wherein an area of a vertical projection of each of the pads on the common electrode is larger than an area of a vertical projection of the corresponding contact electrode on the common electrode.

17. A method for manufacturing an epitaxial base plate according to claim 1, wherein the method comprises:
providing a base plate body;
forming a plurality of bosses arranged on the base plate body in an array;
forming contact electrodes correspondingly on the top of the bosses;
covering the bosses and a region of the base plate body without being covered by the bosses with a planarization layer, and defining a plurality of first through holes on the planarization layer corresponding to the bosses to expose the plurality of contact electrodes via the plurality of first through holes; and
forming a plurality of pads arranged on the planarization layer in an array, the pads being each electrically connected to the corresponding contact electrodes via the corresponding first through holes, an area of a vertical projection of the pads on the base plate body being larger than an area of a vertical projection of the contact electrodes on the base plate body.

18. The method according to claim 17, wherein before the covering the bosses and a region of the base plate body without being covered by the bosses with a planarization layer, the method further comprises:
forming a passivation layer on the bosses, and defining, on the passivation layer, a plurality of second through holes exposing the contact electrodes.

19. The method according to claim 17, wherein after the forming a plurality of pads arranged on the planarization layer in an array, the pads being each electrically connected to the corresponding contact electrodes via the corresponding first through holes, the method further comprises:
performing alignment bonding of the pads and corresponding driving elements on a base.

20. The method according to claim 19, wherein after the performing alignment bonding of the pads and corresponding driving elements on the base, the method further comprises:
removing the base plate body, and forming a common electrode on a side of the bosses away from the pads.
